(19) United States
(12) Patent Application Publication
(10) Pub. No.: US 2010/0176204 A1
(43) Pub. Date: Jul. 15, 2010

(54) IC CHIP

(75) Inventor: Hung Yun Li, Tao Yuan (TW)

Correspondence Address: RABIN & Berdo, PC, 1101 14TH STREET, NW, SUITE 500, WASHINGTON, DC, 20005, US

(73) Assignee: DYNACARD CO. LTD., Taipei (TW)

(21) Appl. No.: 12/354,235

(22) Filed: Jan. 15, 2009

(51) Int. Cl. G06K 19/07; H01L 23/02

(52) U.S. Cl. 235/492; 257/679; 257/E23.002

(57) ABSTRACT

An IC chip comprises a carrier, a memory unit and a contact unit. The carrier has two opposite ends. The memory unit is mounted on one end of the carrier and has multiple parallel memory terminals. The contact unit is mounted on the other end of the carrier and has multiple contact terminals The contact terminal connects to a contact IC smart card.

### FIELD OF THE INVENTION

The invention is an micro Secure Digital card, more particularly, an micro Secure Digital card has functions of a smart card and a memorizing card and connects to an electrical device by wireless communication.

### BACKGROUND OF THE INVENTION

Different conventional plastic cards such as multi-function credit cards and memory cards have been developed and are used in commercial and data communication processes. Some credit cards function as cash by deducting funds from a cash account. Memory cards record or store information or images. Recently, micro Secure Digital cards have been mounted on plastic cards to increase applications of the plastic cards. Such cards are called micro Secure Digital cards and are classified as smart cards and IC memory cards. The smart card, such as an IC credit card or an easy card, may store information for use in commercial transactions. The micro Secure Digital card may be used in mobile phones or cameras to store personal connecting information or images.

With reference to FIG. 3, the contact smart card comprises a main body (30) and a chip (31). The chip (31) is mounted on the main body (30), comprises at least one pin (32) and connects to a specific device to read or store trading information. The pins (32) are mounted in a line on the chip (31) and comprise a Vcc/Vss pin, an I/O pin, a CLK pin, an RST pin, an LA/LB pin and an NC pin.

With further reference to FIG. 4, the contact-less smart card comprises a main body (40), a chip (41), an antenna (42) and a coating (43). The chip (41) is mounted on the main body (40) and stores information. The antenna (42) is circular, is mounted on the main body (40), connects to the chip (41) and transmits information stored on the chip (41) without attaching to an electrical device.

### SUMMARY OF THE INVENTION

The main objective of the present invention is to provide an IC chip that combines functions of a smart card and a memory card and transmits information by wireless communication.

A micro Secure Digital card in accordance with the present invention comprises a carrier, a memory unit and a contact unit. The carrier is rectangular and has two opposite ends. The memory unit is mounted on one end of the carrier and has multiple parallel memory terminals. The contact unit is mounted on the other end of the carrier and has multiple contact terminals. The contact terminal connects to a contact IC smart card.

### BRIEF DESCRIPTION OF THE DRAWINGS

FIG. 1 is a perspective view of a first embodiment of an IC chip in accordance with the present invention.

FIG. 2 is a perspective view of a second embodiment of an IC chip in accordance with the present invention.

FIG. 3 is an exploded perspective view of a conventional contact IC smart card.

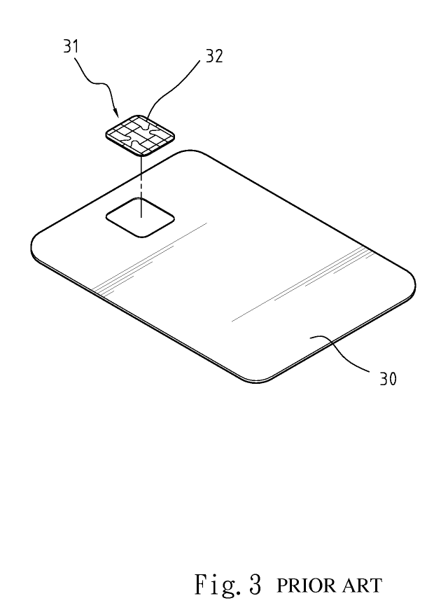

FIG. 4 is an exploded perspective view of a conventional contact-less IC smart card.

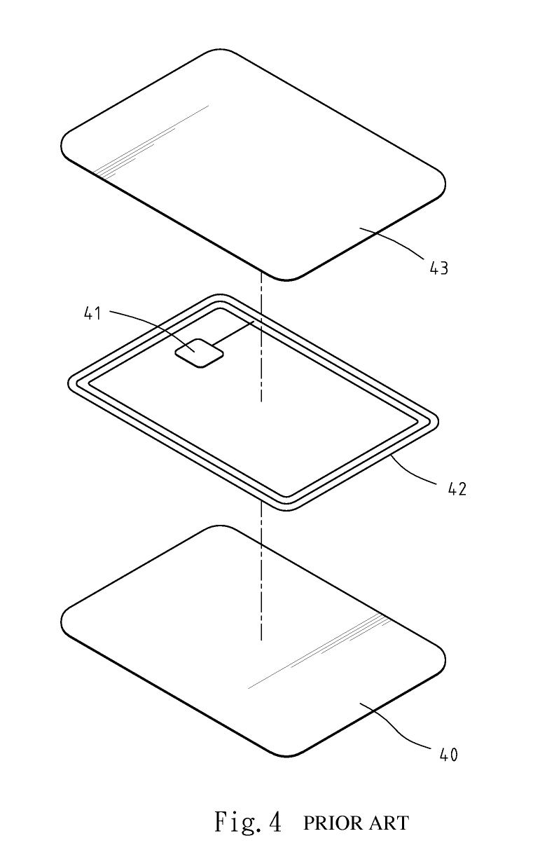

### DESCRIPTION OF THE PREFERRED EMBODIMENT

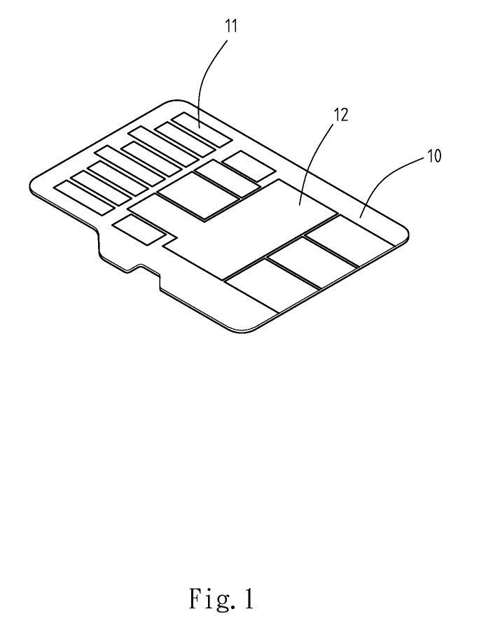

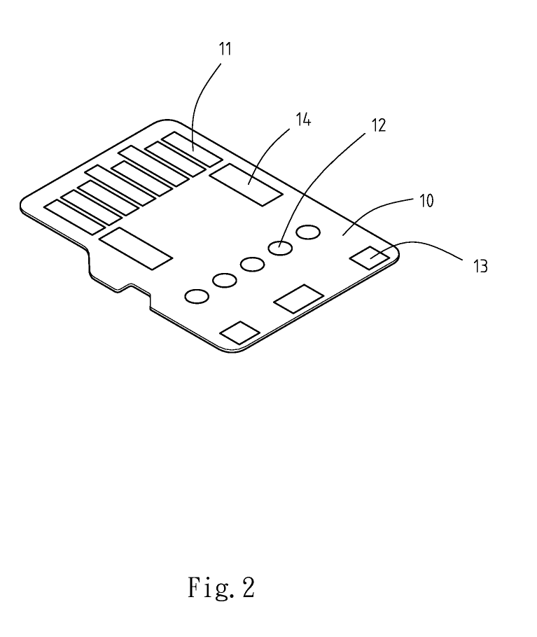

With reference to FIGS. 1 to 2, a micro Secure Digital card in accordance with the present invention comprises a carrier (10), a memory unit (11), a contact unit (12), an optional first output unit (13) and an optional second output unit (14).

The carrier (10) is rectangular and has two opposite ends.

The memory unit (11) is mounted on one end of the carrier (10), has multiple parallel memory terminals and connects to a specific electrical device to read or store information.

The contact unit (12) is mounted on the end opposite to the memory unit (11) of the carrier (10), has multiple parallel contact terminals and connects to a specific electrical device.

The first output unit (13) is mounted next to the contact unit (12) and selectively connects to an external antenna.

The second output unit (14) is mounted between the memory unit (11) and the contact unit (12) and selectively connects to an antenna of an external electrical device.

1. A micro Secure Digital (SD) card comprising:
a rectangular carrier and having a first end and a second end opposite to the first end;
a memory unit mounted on the first end and having eight parallel memory terminals;
a contact unit mounted on the second end and having multiple parallel contact terminals, the contact terminals being connectable to a contact IC smart card;
a first output unit mounted next to the contact unit and being connectable to an external antenna; and
a second output unit mounted between the memory unit and the contact unit, the first output unit being connectable to an antenna of an external electrical device.

2-8. (canceled)

9. The micro Secure Digital (SD) card as claimed in claim 1, wherein the contact unit has five parallel contact terminals.

10-12. (canceled)
